(19) United States
(12) Patent Application Publication
(10) Pub. No.: US 2026/0205105 A1
(43) Pub. Date: Jul. 16, 2026

(54) SEMICONDUCTOR BIASING CIRCUIT

(71) Applicant: TEXAS INSTRUMENTS INCORPORATED, DALLAS, TX (US)

(72) Inventors: Nambi SREEKANTH, KOTHACHERUVU (IN); Vinayak HEGDE, BANGALORE (IN); Ankur CHAUHAN, BENGALURU (IN); Prasad BHUPALAM, HYDERABAD (IN)

(21) Appl. No.: 19/448,774

(22) Filed: Jan. 14, 2026

(30) Foreign Application Priority Data
Jan. 15, 2025 (IN) 202541003528

(51) Int. Cl. H03K 17/082; H10D 89/60

(52) U.S. Cl. CPC H03K 17/0822; H10D 89/819

(57) ABSTRACT

An apparatus includes a semiconductor device having a first semiconductor layer and a second semiconductor layer, and the first semiconductor layer has dopants of opposite polarities. The semiconductor device includes a bias circuit implemented in the first semiconductor layer. The bias circuit has a first terminal, a second terminal, a third terminal, and a fourth terminal. The second terminal is coupled to the first semiconductor layer and the third terminal is coupled to the second semiconductor layer. The bias circuit includes a charge circuit coupled between the first terminal and the third terminal, a discharge circuit coupled between the third terminal and the second terminal, and a rectifying device coupled between the third terminal and the fourth terminal.

### CROSS-REFERENCE TO RELATED APPLICATION

This application claims the benefit of priority to Indian Provisional Application No. 202541003528, filed on 15 January 2025, the entirety of which is herein incorporated by reference.

### BACKGROUND

Electronic fuse (E-fuse) protection systems are employed in power delivery applications to provide controlled current conduction between power input and power output terminals. These systems utilize semiconductor switching devices, such as power field-effect transistors (FETs), to selectively conduct current while monitoring electrical conditions and providing protection functionality. E-fuse protection systems operate across wide voltage ranges and must accommodate various electrical stress conditions including transient events with slew rates that can reach gigavolt-per-second levels and voltage excursions that may extend to negative voltage levels. The systems may include controller circuitry that contains driver circuits for FET control, sense circuitry for output voltage monitoring, input voltage monitoring, load monitoring, and associated biasing circuitry for semiconductor device operation. The sense circuitry may be placed in isolation tank to prevent charge injection to substrate.

### SUMMARY

A first example relates to an apparatus including a semiconductor device having a first semiconductor layer and a second semiconductor layer, and the first semiconductor layer has dopants of opposite polarities. The semiconductor device includes a bias circuit implemented in the first semiconductor layer. The bias circuit has a first terminal, a second terminal, a third terminal, and a fourth terminal. The second terminal is coupled to the first semiconductor layer and the third terminal is coupled to the second semiconductor layer. The bias circuit includes a charge circuit coupled between the first terminal and the third terminal, a discharge circuit coupled between the third terminal and the second terminal, and a rectifying device coupled between the third terminal and the fourth terminal.

A second example relates to an apparatus including a switch coupled between a power input and a power output, the switch having a switch control terminal. The apparatus includes a semiconductor device including a first semiconductor layer, a second semiconductor layer, and a substrate, the first and second semiconductor layers having dopants of opposite polarities, and the second semiconductor layer and the substrate having dopants of opposite polarities. The first semiconductor layer includes a drive circuit, a sense circuit, and a bias circuit. The drive circuit has an input and an output, the output of the drive circuit coupled to the switch control terminal. The sense circuit has an input and an output, the input of the sense circuit is coupled to the power output, and the output of the sense circuit is coupled to the drive circuit. The bias circuit has a first terminal, a second terminal, a third terminal and a fourth terminal, the second terminal is coupled to the power output, and the third terminal is coupled to the second semiconductor layer. The bias circuit includes a charge circuit coupled between the first terminal and the third terminal. The bias circuit includes a discharge circuit coupled between the third terminal and the second terminal, and a rectifying device coupled between the third terminal and the fourth terminal.

A third example relates to a device including a transistor coupled between a power input and a power output. The transistor has a control terminal. The device includes control and sensing circuitry coupled to the power input, power output, and the control terminal, the control and sensing circuitry being on an isolation tank and a semiconductor substrate. The device also includes a biasing circuit coupled to the power input, the power output, and the isolation tank. The bias circuit is configurable to charge the isolation tank responsive to a rising voltage at the power output, discharge the isolation tank responsive to a falling voltage at the power output, and maintain a non-zero voltage at the isolation tank responsive to a negative voltage at the power output.

### BRIEF DESCRIPTION OF THE DRAWINGS

FIG. 1 is a schematic illustrating an electronic fuse (E-fuse) protection system, according to various examples.

FIG. 2 is a schematic illustrating a cross-sectional view of a semiconductor device including part of the E-fuse protection system from FIG. 1, according to various examples.

FIG. 3 is a schematic illustrating a bock level representation of bias circuitry of the E-fuse protection system of FIG. 1, according to various examples.

FIG. 4 is a schematic illustrating circuit elements of bias circuitry of the E-fuse protection system of FIG. 1, according to various examples.

FIG. 5 is a schematic illustrating an internal voltage generator circuit that can be part of the bias circuity of FIGS. 3 and 4, according to various examples.

FIG. 6 is a schematic illustrating an offset voltage generator circuit that can be part of the bias circuity of FIGS. 3 and 4, according to various examples.

FIGS. 7A and 7B are schematics illustrating operations of the bias circuitry of FIGS. 3 and 4, according to various examples.

FIGS. 8A and 8B are schematics illustrating operations of the bias circuitry of FIGS. 3 and 4, according to various examples.

FIGS. 9A and 9B are schematics illustrating operation of the bias circuitry of FIGS. 3 and 4, according to various examples.

FIG. 10 includes a graph illustrating operations of the bias circuitry of FIGS. 3 and 4, according to various examples.

FIG. 11 is a schematic illustrating a cross-sectional view of the semiconductor device of FIG. 2, according to various examples.

FIG. 12 is a schematic illustrating a semiconductor package of the E-fuse protection system from FIG. 1, according to various examples.

The same reference numbers or other reference designators are used in the drawings to designate the same or similar (either by function and/or structure) features.

### DETAILED DESCRIPTION

As described above, sense circuitry of E-fuse protection systems may be placed in isolation tank to prevent charge injection to substrate. Semiconductor isolation tank structures within E-fuse protection systems utilize multiple doped semiconductor layers including P-type epitaxial (PEPI) layers and N-type buried layers (NBL) to provide electrical isolation between active circuits and substrate regions. The voltage relationships between these semiconductor layers may be controlled with biasing to maintain PN junctions in reverse-bias and prevent charge injection to substrate areas around the semiconductor isolation tank structures.

Some static biasing approaches for semiconductor isolation tanks may create voltage buildup that exceeds junction breakdown limits during high slew rate transients or may allow substrate junctions to become forward biased during negative voltage excursions, resulting in latch-up conditions and device malfunction across different types of protection circuit implementations.

This description relates to an adaptive biasing circuit for semiconductor isolation tank nodes of an electronic fuse (E-fuse) protection system. The adaptive biasing circuit can prevent (or reduce) charge injection into substrates and maintain electrical isolation within semiconductor structures, which allows the E-fuse protection system to maintain a stable operation during electrical stress conditions. Examples of the adaptive biasing techniques to be described herein can address these issues by maintaining controlled voltage relationships between semiconductor layers during electrical stress conditions and preserving proper isolation characteristics during normal operating conditions.

In various examples, an E-fuse protection system can implement a bias circuit to, for example, maintain proper voltage levels at isolation tank structures and prevent charge injection to substrate regions, and generate biasing signals responsive to voltage conditions at an output terminal to, for example, reduce voltage differences between semiconductor layers that exceed junction breakdown limits and prevent forward biasing of substrate junctions that could trigger latch-up conditions. The bias circuit can also monitor voltage conditions at the output terminal relative to multiple operational thresholds, and provide appropriate biasing behaviors across distinct operational modes. During intervals of time the output terminal experiences rising voltage conditions, the bias circuit may source charging current from an input terminal and maintain the isolation tank structure voltages that track output voltage transitions to prevent violation of well voltage ratings. During intervals of time that the output terminal experiences falling voltage transients, the bias circuit may provide discharge paths with controlled breakdown characteristics to limit voltage buildup between semiconductor layers within semiconductor process limits, creating rapid discharge capability that prevents voltage differences from exceeding junction breakdown voltages responsible for device malfunction. During intervals of time that the output terminal experiences negative voltage conditions, which can indicate inductive kickback or other transient phenomena, the bias circuit provides current conduction from internal voltage sources to maintain tank nodes at positive voltage levels. This adaptive approach curtails latch-up conditions and reduces the likelihood of device failure during electrical stress events.

Furthermore, for high-voltage E-fuse protection applications, the bias circuit according to examples described herein can provide additional benefits, such as preventing or reducing the likelihood of supply rail collapse by drawing charging current from stable input supplies during extended high slew rate operation periods. In E-fuse protection systems, some biasing approaches may rely on derived supply voltages that have limited current sourcing capability, and high slew rate transients can result in supply rail collapse when charging current demands exceed the capability of weaker internal voltage sources. The adaptive biasing approach described herein may ensure that the isolation tank structures receive adequate current from stable supply rails during transient events, curtailing voltage buildup that could cause junction breakdown and preventing charge injection to substrate regions that can cause latch-up conditions during electrical stress operations.

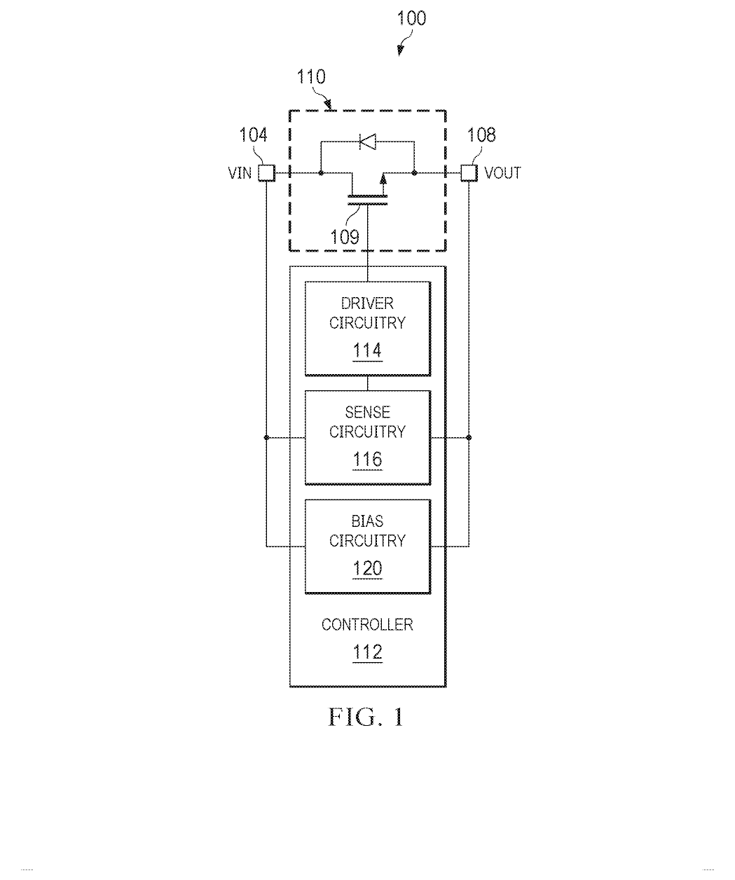

FIG. 1 illustrates an electronic fuse (E-fuse) protection system 100 that provides protection against negative voltage transients and high slew rate events, according to various examples. The protection system 100 includes a power input terminal 104 configured to receive an input voltage VIN and a power output terminal 108 configured to provide an output voltage VOUT to a downstream load. The protection system 100 includes a transistor, such as a field-effect transistor (FET) 110, coupled between the power input terminal 104 and the power output terminal 108. The FET 110 comprises an n-channel FET (NFET) device that can (or is configured to or configurable to) control the flow of current from the power input terminal 104 to the power output terminal 108 based on cont provides the primary switching function for power delivery from VIN to VOUT and can handle high current levels and maintains low drain-to-source on-resistance (Rdson) characteristics.

The protection system 100 includes a controller 112 that contains driver circuitry 114, sense circuitry 116, and bias circuitry 120. The driver circuitry 114 can control the FET 110 by providing control signals to the control terminal 109 of the FET 110. The driver circuitry 114 regulates current flow and provides protection against fault conditions, including overcurrent, overvoltage, and short circuit events. The driver circuitry 114 generates switching signals to turn the FET 110 on and off based on feedback from the sense circuitry 116 and predetermined protection parameters.

The sense circuitry 116 is coupled to the power input terminal 104 and the power output terminal 108. The sense circuity 116 can monitor voltage conditions at the power output terminal 108. The sense circuitry 116 can detect transient events, negative voltage excursions, and fault conditions that may occur at the power output terminal 108. The sense circuitry 116 provides feedback signals to the driver circuitry 114 to enable responsive protection actions based on detected conditions. The sense circuitry 116 implements signal processing functionality to continuously monitor VOUT at the power output terminal 108 and assess whether the protection system 100 is experiencing fault conditions that need protective action.

The bias circuitry 120 can provide adaptive biasing for isolation tank structures of the sense circuitry 116. The bias circuitry 120 is coupled to the power input terminal 104, the power output terminal 108, and internal voltage references to maintain proper bias voltages for the isolation tank structures. The bias circuitry 120 compensates for high slew rate transients of up to about 1 gigavolt per second (GV/s) and negative voltage conditions of up to about -5 volts (V) that can cause latch-up or violation of semiconductor junction voltage ratings that may damage the controller 112 housing the bias circuitry 120. The bias circuitry 120 includes charge circuits, discharge circuits, and rectifying devices that adaptively respond to voltage conditions at the power output terminal 108 to prevent charge injection to a substrate and maintain electrical isolation within semiconductor structures.

The protection system 100 can support voltage ranges from approximately -5 V to +80 V at the power output terminal 108 and handle transient slew rates of up to about 1 GV/s. The biasing strategy provided by the bias circuitry 120 enables the sense circuitry 116 to operate reliably during stress conditions while maintaining proper isolation and preventing device malfunction or failure. In various examples, the FET 110 and the controller 112 can be implemented on separate semiconductor dies within a multi-chip module package, with the controller 112 implemented using a first semiconductor technology and the FET 110 implemented using a vertical FET technology tuned for high-power switching applications.

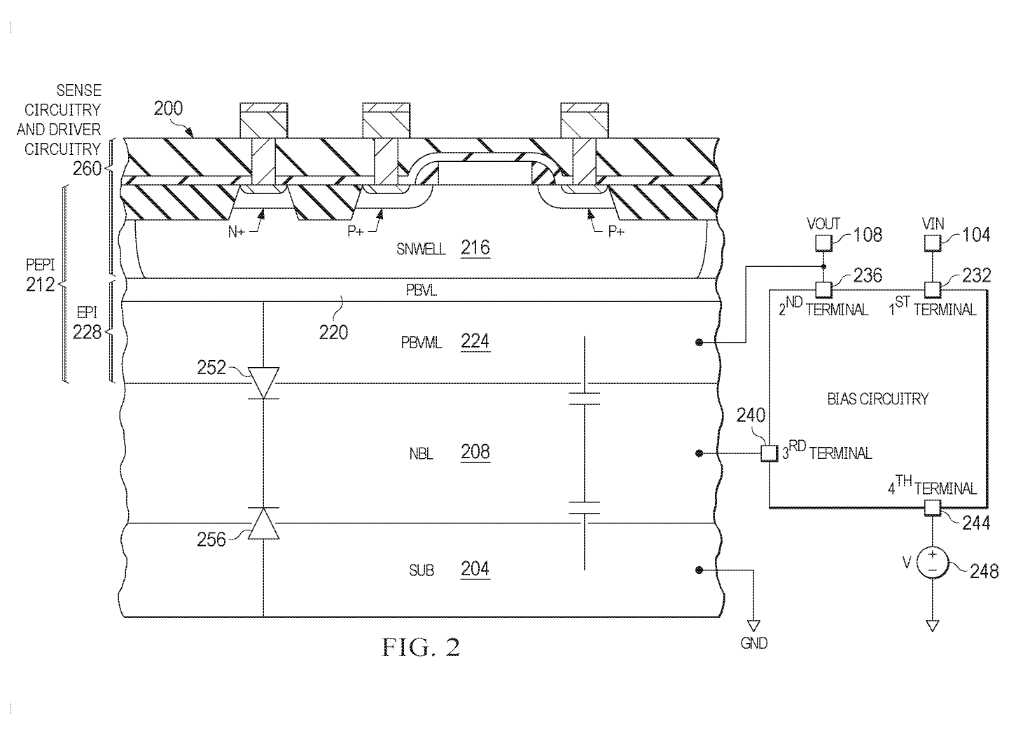

FIG. 2 illustrates a semiconductor device structure 200 that can be part of E-fuse protection system 100 of FIG. 1, according to various examples. More specifically, FIG. 2 provides a cross-sectional view of the semiconductor device structure 200 demonstrating how the bias circuitry 120 interfaces with the isolation tank structures to provide adaptive biasing for isolation tank structures within the sense circuitry 116. The semiconductor device structure 200 includes a substrate layer (SUB) 204 formed with a P-type doped substrate that provides a foundational semiconductor structure. The semiconductor device structure 200 includes an N-type doped buried layer (NBL) 208 formed on the substrate layer 204. The NBL 208 is an isolation tank structure configured to provide electrical isolation between circuits and the substrate layer 204. The semiconductor device structure 200 includes a P-type doped epitaxial (PEPI) layer 212 formed on the NBL 208 and configured to support active device structures and provide isolation tank functionality for the sense circuitry 116. Thus, the NBL 208 and the PEPI layer 212 have dopants of opposite polarities to form an n-channel metal oxide semiconductor (NMOS).

The semiconductor device structure 200 demonstrates the specific implementation of the bias circuitry 120 from FIG. 1, and illustrates how the bias circuitry 120 connects to and controls the various semiconductor layers. The semiconductor device structure 200 includes multiple doped regions formed within the PEPI layer 212 to support various circuit elements within the sense circuitry 116. The semiconductor device structure 200 includes an N-type shallow well (SNW) region 216 formed within the PEPI layer 212 that may be configured to provide body connections for P-type metal-oxide-semiconductor (PMOS) devices. The semiconductor device structure 200 includes P-type body low voltage (PBLV) regions 220 and P-type body medium voltage (PBLMV) regions 224 formed within the PEPI layer 212 to provide body connections for different voltage rating specifications. The semiconductor device structure 200 includes an epitaxial (EPI) region 228 formed within the PEPI layer 212 and configured to support high-voltage device structures.

The bias circuitry 120 from FIG. 1 can be in the same semiconductor die including that semiconductor device structure 200, and interfaces with the semiconductor device structure 200 through specific terminal connections that provide electrical access to the various semiconductor layers and regions. The semiconductor device structure 200 includes a first terminal 232 (shown on the bias circuitry 120) electrically coupled to the power input terminal 104 of FIG. 1 and configured to receive the input voltage VIN. The semiconductor device structure 200 includes a second terminal 236 electrically coupled to the power output terminal 108 of FIG. 1 and to the PEPI layer 212, with the second terminal 236 configured to provide a connection between the output voltage VOUT and the PEPI layer 212 for VOUT-referenced operations. The semiconductor device structure 200 includes a third terminal 240 electrically coupled to the NBL 208 and configured to provide bias control for the isolation tank structure. The semiconductor device structure 200 includes a fourth terminal 244 configured to receive an internal voltage VINT from a voltage source 248 that provides a predetermined reference voltage for biasing operations performed by the bias circuitry 120. In some examples, the bias circuitry 120 can be implemented in the PEPI layer 212.

FIG. 2 also illustrates inherent junction diodes formed between the semiconductor layers, which can be biased by the bias circuitry 120 using an adaptive biasing scheme, as to be described below. The semiconductor device structure 200 includes a first inherent diode 252 formed between the PEPI layer 212 and the NBL 208 because of the opposite dopant polarities. The first inherent diode 252 is formed with a P-N junction diode that provides isolation characteristics between the layers. The semiconductor device structure 200 includes a second inherent diode 256 formed between the NBL 208 and the substrate layer 204, with the second inherent diode 256 formed of an N-P junction diode that prevents charge injection to the substrate layer 204 when maintained in reverse-bias by the bias circuitry 120. The first inherent diode 252 and the second inherent diode 256 provide electrical isolation and prevent latch-up conditions when properly biased during normal and fault conditions through the adaptive bias provided by the bias circuitry 120.

The semiconductor device structure 200 includes sense circuitry and driver circuitry 260 implemented within the isolation tank formed by the NBL 208 and PEPI layer 212, representing the physical implementation of the driver circuitry 114 and sense circuitry 116 of FIG. 1. The sense circuitry and driver circuitry 260 are electrically isolated from the substrate layer 204 through the reverse-biased junction of the second inherent diode 256 when properly biased by the bias circuitry 120. The sense circuitry and driver circuitry 260 includes signal processing functionality to monitor voltage conditions at the second terminal 236 and to provide control signals for protection operations. Due to the biasing of the NBL 208 through the third terminal 240 by the bias circuitry 120, The sense circuitry and driver circuitry 260 can be electrically isolated by the inherent diodes, and charge injection to the substrate layer 204 can be prevented during transient or steady state conditions.

As demonstrated, the bias circuitry 120 is coupled to the first terminal 232, the second terminal 236, the third terminal 240, and the fourth terminal 244 to provide the adaptive biasing functionality described in the system-level view of FIG. 1. The bias circuitry 120 maintains proper voltage relationships between the PEPI layer 212 and NBL 208 to prevent violation of semiconductor junction voltage ratings during high slew rate transients and negative voltage excursions. The bias circuitry 120 sources current from the first terminal 232 and the second terminal 236, providing a current path to the third terminal 240 during rising voltage conditions at the second terminal 236. The bias circuitry 120 also provides discharge paths during falling voltage transients, and conducts current from the fourth terminal 244 during negative voltage conditions to maintain reverse-bias across the second inherent diode 256. The adaptive biasing strategy implemented by the bias circuitry 120 enables the semiconductor device structure 200 to support a voltage (e.g., VOUT) that ranges from approximately -5 V to +80 V at the second terminal 236, and maintains electrical isolation and curtails device malfunction during stress conditions.

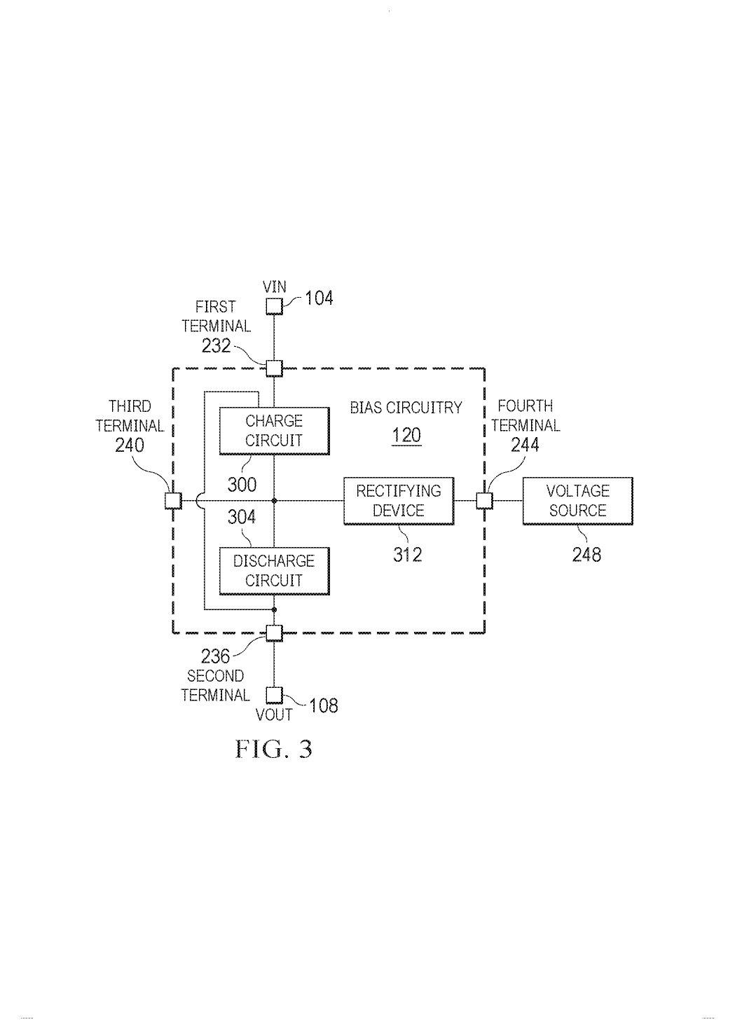

FIG. 3 illustrates block diagram representation of the bias circuitry 120 of FIG. 1 that includes the functional circuit blocks and terminal connections that provide adaptive biasing for isolation tank structures, according to various examples. FIG. 3 demonstrates the conceptual architecture of how the bias circuitry 120 interfaces with the power input terminal 104 and the power output terminal 108 to maintain proper bias voltages for isolation tank structures within the sense circuitry 116. The bias circuitry 120 includes the first terminal 232 electrically coupled to the power input terminal 104 and configured to receive the input voltage VIN. The bias circuitry 120 includes the second terminal 236 electrically coupled to the power output terminal 108 and configured to provide connection to the output voltage VOUT. The bias circuitry 120 includes the third terminal 240 configured to provide bias control for isolation tank structures, and the fourth terminal 244 configured to receive an internal voltage VINT from the voltage source 248.

The bias circuitry 120 includes a charge circuit 300 coupled between the first terminal 232, the second terminal 236, and the third terminal 240. The charge circuit 300 can source charging current from the input voltage VIN and the output voltage VOUT during rising voltage conditions at the second terminal 236 to maintain the third terminal 240 at a voltage level that follows the output voltage VOUT. The charge circuit 300 provides sufficient drive current from the first terminal 232 during transient events to ensure proper biasing of isolation tank structures and prevent voltage differences from exceeding semiconductor junction breakdown limits. Stated differently, the charge circuit 300 operates as a current source that may supply enough electrical current during rapid voltage changes to keep the NBL and PEPI semiconductor layers properly biased. Additionally, the charge circuit 300 is coupled to an internal voltage source of VOUT+5V. Because of this coupling, the voltage of NBL at third terminal 240 tracks the PEPI layer voltage at second terminal 236 (e.g., at a voltage of VOUT+5V minus a gate-source voltage (VGS), as to be described below), thereby maintaining the voltage difference between the PEPI layer and the NBL within acceptable limits during charging operations. During high-speed transient events with slew rates up to approximately 1 GV/s, the charge circuit 300 provides rapid charging capability to prevent voltage buildup that could exceed these semiconductor junction breakdown limits. The charge circuit 300 enables fast charging of isolation tank capacitances while drawing current from the stable VIN supply rather than from weaker derived supplies.

The bias circuitry 120 includes a discharge circuit 304 coupled between the third terminal 240 and the second terminal 236. The discharge circuit 304 can provide a discharge path (e.g., set discharge) for isolation tank structures during falling voltage transients at the second terminal 236. The discharge circuit 304 limits voltage buildup between semiconductor tank layers within well voltage ratings during high slew rate events. The discharge circuit 304 enables rapid discharge (e.g., of charge stored between NBL and the substrate) to prevent violation of semiconductor junction voltage ratings when the output voltage VOUT experiences falling transients with slew rates up to about 1 GV/s.

The bias circuitry 120 includes a rectifying device 312 coupled between the third terminal 240 and the fourth terminal 244. The rectifying device 312 can conduct current from the voltage source 248 to the third terminal 240 during negative voltage conditions at the second terminal 236. The rectifying device 312 maintains the third terminal 240 at a positive (or at least non-negative) voltage level to prevent forward biasing of substrate junctions and associated latch-up conditions when the output voltage VOUT becomes negative. The rectifying device 312 ensures that isolation tank structures remain properly biased even during negative voltage excursions of up to about -5 V (or other threshold level) at the second terminal 236.

The voltage source 248 outputs the internal voltage VINT to support biasing operations during negative voltage conditions at the power output terminal 108. The internal voltage VINT output by the voltage source 248 may be a predetermined reference voltage, such as about 5 V, and serves as a stable supply for the rectifying device 312. The adaptive biasing architecture shown in FIG. 3 enables the bias circuitry 120 to respond to three different operational modes based on voltage conditions at the second terminal 236, including charge mode during rising voltages, discharge mode during falling transients, and negative protection mode during negative voltage excursions. The charge circuit 300, the discharge circuit 304 and the rectifying device 312 operate in concert to maintain electrical isolation within semiconductor structures while preventing charge injection to substrate regions during electrical stress conditions.

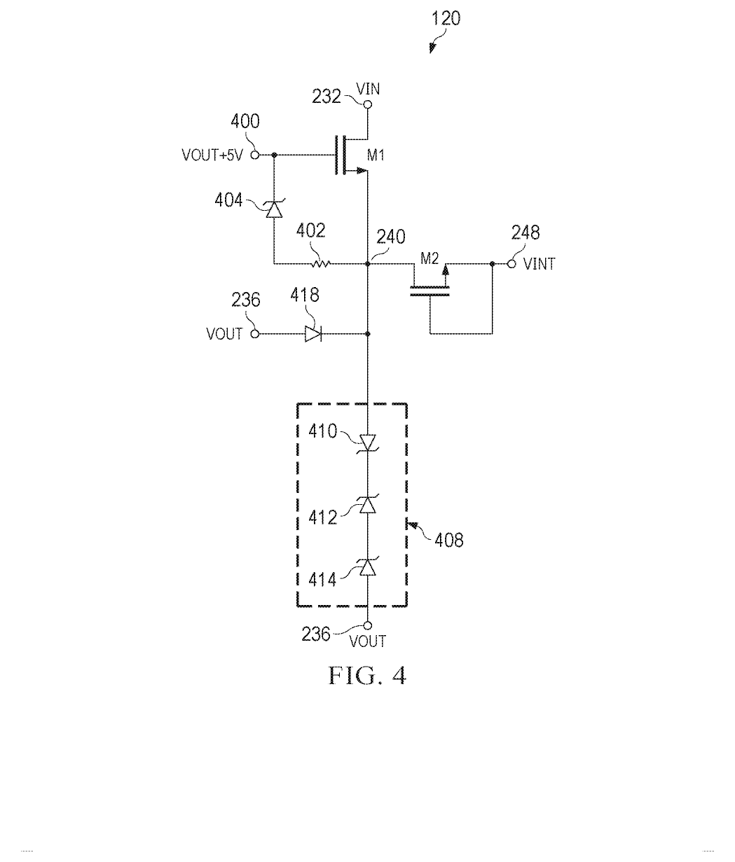

FIG. 4 illustrates a detailed circuit implementation of the bias circuitry 120 from FIGS. 1-3, showing the specific circuit elements that provide adaptive biasing for isolation tank structures during different operational conditions, according to various examples. FIG. 4 demonstrates an example of how the functional blocks described in FIG. 3 may be implemented using circuit components to provide the adaptive biasing strategy for high slew rate transients and negative voltage conditions. The bias circuitry 120 includes the first terminal 232 configured to receive the input voltage VIN, the second terminal 236 configured to receive the output voltage VOUT, the third terminal 240 configured to provide bias control to the NBL, and the fourth terminal 244 configured to receive the internal voltage VINT from the voltage source 248.

The bias circuitry 120 includes the charge circuit 300 implemented using a first transistor M1 (an NFET) configured as a source follower circuit. The first transistor M1 has a drain terminal coupled to the first terminal 232 (VIN), a gate terminal coupled to an offset voltage generator 400, and a source terminal coupled to the third terminal 240 (NBL). The bias circuitry 120 includes a resistor 402 and a diode 404 (a Zener diode) coupled between the gate terminal and the source terminal (as well as the third terminal 240) of the first transistor M1. The resistor 402 and the diode 404 provide gate-to-source voltage limiting for the first transistor M1 and facilitates establishing proper bias conditions during transient events. The offset voltage generator 400 can generate a gate bias voltage VOUT+5V by adding a predetermined voltage offset of about 5 V to the output voltage VOUT received at the second terminal 236. The first transistor M1 provides the charging functionality described in the charge circuit 300 of FIG. 3 by sourcing current from the first terminal 232 through the drain-source path of the transistor M1 during rising voltage conditions at the second terminal 236 (VOUT). With the source follower arrangement, the voltage at NBL (third terminal 240) can be at VOUT+5V-VGS, where VGS is the gate-source voltage of the transistor M1, thereby maintaining the voltage difference between the PEPI layer and the NBL within acceptable limits during charging operations.

The bias circuitry 120 includes the discharge circuit 304 implemented using a diode stack 408 coupled between the third terminal 240 and the second terminal 236. In FIG. 4, a stack of Zener diodes is shown. In other examples, diode stack 408 can include other types of diodes. The Zener diode stack 408 includes diodes arranged in series to provide a controlled discharge path during falling voltage transients at the second terminal 236. The Zener diode stack 408 provides the discharge functionality described in the discharge circuit 304 of FIG. 3 by creating a conductive path that limits voltage buildup between the third terminal 240 and the second terminal 236 during high slew rate falling transients. The Zener diode stack 408 can conduct responsive to the voltage difference between the third terminal 240 and the second terminal 236 reaching a predetermined breakdown voltage, thereby preventing the voltage difference from exceeding semiconductor junction voltage ratings.

The Zener diode stack 408 includes a first diode 410, a second diode 412 and a third diode 414, which may be implemented as Zener diodes in some examples. The first diode 410 has an anode coupled to the third terminal 240 (NBL) and a cathode coupled to a cathode of the second diode 412. The third diode has an anode coupled to the second terminal 236 and a cathode coupled to an anode of the second diode 412.

In FIG. 4, a diode 418 is shown coupled to the second terminal 236, with the diode 418 representing the first inherent diode 252 of FIG. 2 formed between semiconductor layers as part of device construction. More specifically, the diode 418 represents the parasitic junction diode that exists between the PEPI layer 212 and the NBL 208 in the semiconductor device structure 200 of FIG. 2 and provides bias functionality during intervals of time the VOUT+5V supply rail is not available.

The bias circuitry 120 also includes the rectifying device 312 implemented using a second transistor M2 (an NFET) coupled between the third terminal 240 (NBL) and the fourth terminal 244. The second transistor M2 has a source terminal coupled to the voltage source 248, a drain terminal coupled to the third terminal 240 (NBL), and a gate terminal that may be coupled to the source terminal to maintain the second transistor M2 in a non-conducting state during normal operation. The second transistor M2 provides the rectifying functionality described in the rectifying device 312 of FIG. 3 through an inherent body diode of the second transistor M2, which conducts current from the voltage source 248 to the third terminal 240 responsive to the second terminal 236 experiencing negative voltage conditions. The body diode of the second transistor M2 maintains the third terminal 240 (NBL) at a voltage level of approximately VINT minus the forward voltage drop of the body diode during negative voltage excursions at the second terminal 236, which can prevent the voltage at the third terminal 240 from becoming negative (or lower than the substrate voltage) and forward biasing the diode 256. In some examples, the second transistor M2 can be replaced by a diode.

The offset voltage generator 400 provides the gate bias voltage VOUT+5V to enable proper operation of the first transistor M1 across varying voltage conditions at the second terminal 236. The offset voltage generator 400 ensures that the first transistor M1 maintains sufficient gate-to-source voltage to operate in the desired region during charging operations, whether in saturation mode during initial charging or linear mode during steady-state conditions. The voltage source 248 provides the internal voltage VINT, which may be about 5 V and is generated from the input voltage VIN through internal voltage regulation circuitry within the controller 112.

During rising voltage conditions at the second terminal 236, the first transistor M1 operates as a source follower to charge the third terminal 240 to a voltage level that tracks the second terminal 236, with the actual voltage level being VOUT+5V minus the gate-to-source voltage of the first transistor M1 when operating in saturation, or approaching VIN when operating in the linear region. During falling voltage transients at the second terminal 236, the Zener diode stack 408 provides a rapid discharge path to prevent excessive voltage buildup between the third terminal 240 and the second terminal 236. During negative voltage conditions at the second terminal 236, the body diode of the second transistor M2 conducts current from the voltage source 248 to maintain the third terminal 240 at a positive voltage level, preventing forward biasing of substrate junctions and associated latch-up conditions.

The circuit implementation shown in FIG. 4 enables the bias circuitry 120 to handle transient slew rates of up to about 1 GV/s and voltage excursions ranging from approximately -5 V to +80 V at the second terminal 236. The combination of the first transistor M1, the Zener diode stack 408, and the second transistor M2 with the inherent body diode provides comprehensive protection for isolation tank structures by maintaining proper voltage relationships between isolation layers while preventing charge injection to substrate regions during electrical stress conditions.

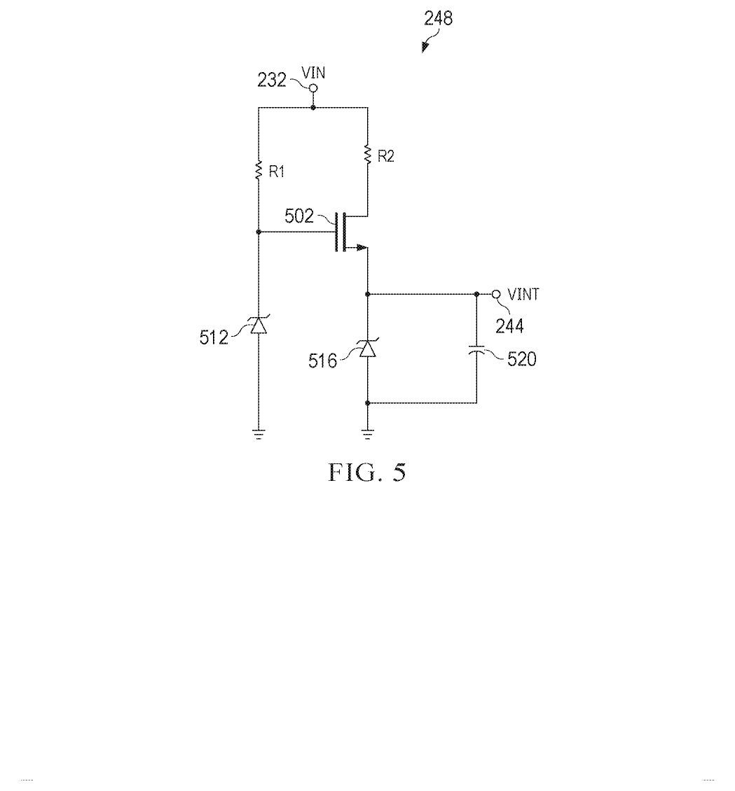

FIG. 5 illustrates the voltage source 248 from FIGS. 3-4, showing the specific circuit elements that generate the internal voltage VINT for biasing operations, according to various examples. FIG. 5 demonstrates the VINT generator circuit that provides the predetermined reference voltage used by the rectifying device during negative voltage conditions at the second terminal 236. The voltage source 248 includes an input coupled to the first terminal 232 to receive the input voltage VIN and an output coupled to the fourth terminal 244 that provides the internal voltage VINT.

The voltage source 248 includes a transistor 502 (an NFET) having a drain terminal, a gate terminal, and a source terminal. The voltage source 248 includes a first resistor R1 coupled between the first terminal 232 and the gate terminal of the transistor 502. The voltage source 248 includes a second resistor R2 coupled between the gate terminal and the drain terminal of the transistor 502. In various examples, the first resistor R1 has a resistance value of approximately 10 megaohms (MΩ) and the second resistor R2 has a resistance value of approximately 1 kilohm (kΩ). The source terminal of the transistor 502 provides the internal voltage VINT at the fourth terminal 244.

The voltage source 248 includes diodes illustrated as Zener diodes, but in some examples, other types of diodes may be employed. The voltage source 248 includes a first Zener diode 512 coupled between the gate terminal of the transistor 502 and ground. The first Zener diode 512 provides voltage regulation to maintain the internal voltage VINT at a stable level despite variations in the input voltage VIN. The voltage source 248 includes a second Zener diode 516 coupled in parallel with the first Zener diode 512 to provide additional voltage regulation and current handling capability. The voltage source 248 includes an output capacitor 520 coupled between the fourth terminal 244 and ground to provide filtering and energy storage for the internal voltage VINT. The output capacitor 520 has a capacitance value of approximately 10 picofarads (pF) in some examples.

The transistor 502, resistor values, and Zener diode characteristics are selected to generate an internal voltage VINT of approximately 5 V from input voltage VIN values ranging from about 9 V to about 80 V. The voltage source 248 provides sufficient current capability to support the rectifying device operations while maintaining voltage regulation during transient conditions.

The circuit of FIG. 5 provide voltage regulation through coordinated interaction between the transistor 502, resistor network, and Zener diodes to generate a stable internal voltage VINT from the varying input voltage VIN. In operation, the input voltage VIN is applied through the first resistor R1 to the gate terminal of the transistor 502, and the second resistor R2 provides feedback from the drain terminal to the gate terminal to establish the operating point of the transistor 502. The transistor 502 operates as a voltage regulator where the gate voltage is determined by the voltage divider action of the first resistor R1 and the second resistor R2, with the source terminal providing the regulated output voltage VINT. The first Zener diode 512 and the second Zener diode 516 provide additional voltage regulation by clamping the gate voltage to prevent excessive voltage levels and maintain stable operation across varying input conditions. The output capacitor 520 filters the internal voltage VINT and provides energy storage to handle transient current demands from the rectifying device operations.

The VINT generator circuit shown in FIG. 5 enables the bias circuitry 120 to maintain proper biasing of isolation tank structures even when the second terminal 236 experiences negative voltage excursions. The stable internal voltage VINT provided by the voltage source 248 ensures that the rectifying device 312 of FIG. 3 can conduct current to the third terminal 240 during negative voltage conditions, preventing forward biasing of substrate junctions and associated latch-up conditions. The voltage regulation provided by the first Zener diode 512 and the second Zener diode 516 ensures consistent performance (or nearly consistent) across varying input voltage conditions and load specifications.

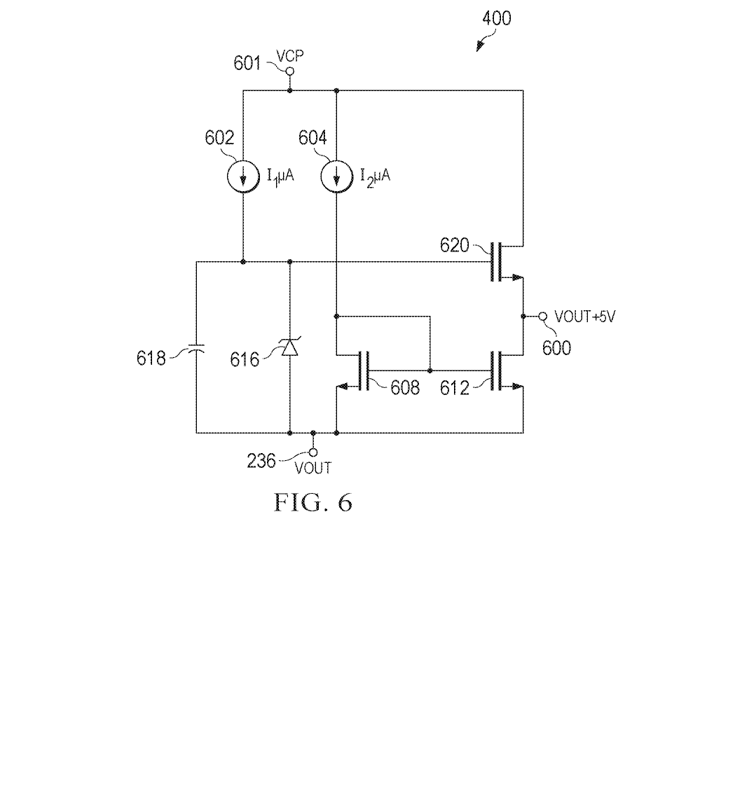

FIG. 6 illustrates the offset voltage generator 400 from FIG. 4, demonstrating an example of circuit elements that generate the gate bias voltage VOUT+5V for the first transistor M1, according to various examples. FIG. 6 demonstrates how the offset voltage generator 400 provides the predetermined offset voltage (VOUT+5V) at an output terminal 600 used to control the source follower during rising voltage conditions at the second terminal 236. The offset voltage generator 400 receives operating power from a charge pump voltage VCP to an input terminal 601 provided by the controller 112 of FIG. 1 and generates an output voltage that tracks the second terminal 236 with a predetermined offset.

The offset voltage generator 400 includes a first current source 602 configured to provide a first current I₁ having a first magnitude, such as about 1 microampere (µA) in one example. The offset voltage generator 400 includes a second current source 604 configured to provide a second current I₂ having a second magnitude that is greater than the first magnitude, such as about 2 µA in one example. The first current source 602 and the second current source 604 are coupled to receive operating power from the charge pump voltage VCP at the input terminal 601, which is provided by charge pump circuitry within the controller 112. The charge pump voltage VCP provides a regulated supply voltage that enables the offset voltage generator 400 to maintain stable operation across varying conditions at the second terminal 236.

The offset voltage generator 400 includes a first transistor 608 (an NFET), a second transistor 612 (an NFET), a diode 616, a capacitor 618 and an output transistor 620 (an NFET) that operate in concert to generate the gate bias voltage VOUT+5V. The first transistor 608 has a drain terminal coupled to the second current source 604, a gate terminal coupled to its own drain terminal to form a diode connection, and a source terminal coupled to the second terminal 236 (VOUT). The second transistor 612 has a gate terminal coupled to the gate terminal of the first transistor 608, a drain terminal coupled to the output terminal 600, and a source terminal coupled to the second terminal 236 (VOUT). The diode 616 has a cathode coupled to a gate terminal of the output transistor 620 and to the capacitor 618. The output transistor 620 has a source terminal coupled to the output terminal 600 and a drain terminal coupled to the input terminal 601 (VCP). The capacitor 618 is also coupled to the second terminal 236 (VOUT) and has a capacitance of about 10 pF in some examples. The source terminal of the output transistor 620 provides the gate bias voltage VOUT+5V to the gate terminal of the first transistor M1 in FIG. 4 through the output terminal 600.

The offset voltage generator 400 provides controlled voltage generation through coordinated interaction between the current sources, transistor current mirror configuration, and the output transistor 620 to generate the stable VOUT+5V reference voltage across varying operating conditions. During operation, the charge pump voltage VCP provides operating power to the first current source 602 and the second current source 604, with the first current source 602 providing the reference current I₁ and the second current source 604 providing the bias current I₂ for the current mirror configuration. The second current source 604 establishes the operating point for the first transistor 608 by providing bias current through the diode-connected configuration, with the gate voltage of the first transistor 608 determined by the current flowing through the second current source 604 and the voltage drop across the drain-to-source path of the first transistor 608.

The current mirror formed by the first transistor 608 and the second transistor 612 operates to replicate the bias conditions established by the second current source 604, with both transistors having gate terminals coupled together and source terminals coupled to the second terminal 236 (VOUT). The second transistor 612 mirrors the current established by the second current source 604 flowing through the first transistor 608, creating a controlled current flow through the output transistor 620. The current flow through the second transistor 612 passes through the output transistor 620, generating voltage drops that establish the predetermined offset relationship between the second terminal 236 and the output voltage VOUT+5V.

The diode 616 provides an additional voltage drop in series with the output transistor 620, with both voltage drops combining to create the approximately 5 V offset above the voltage at the second terminal 236 (VOUT). The total voltage at the source of the output transistor 620 equals the voltage at the second terminal 236 plus the reverse breakdown voltage drop of the diode 616 minus the gate-to-source voltage of the output transistor 620, providing the stable VOUT+5V reference that tracks changes in VOUT while maintaining the predetermined offset.

The charge pump voltage VCP at the input terminal 601 may ensure adequate operating headroom for the first current source 602 and the second current source 604 across the operating range of the second terminal 236, enabling consistent operation when VOUT varies from approximately -5 V to +80 V. The current source-based architecture provides improved power supply rejection and temperature stability compared to resistor-based voltage divider approaches, maintaining consistent offset voltage generation despite variations in the charge pump voltage VCP or load conditions on the VOUT+5V output. The offset voltage generator 400 responds dynamically to changes in voltage at the second terminal 236, ensuring that the first transistor M1 of FIG. 4 receives adequate gate bias voltage to operate properly as a source follower during charging operations while maintaining the desired voltage tracking relationship between the third terminal 240 (NBL) and the second terminal 236 (VOUT) across operating conditions.

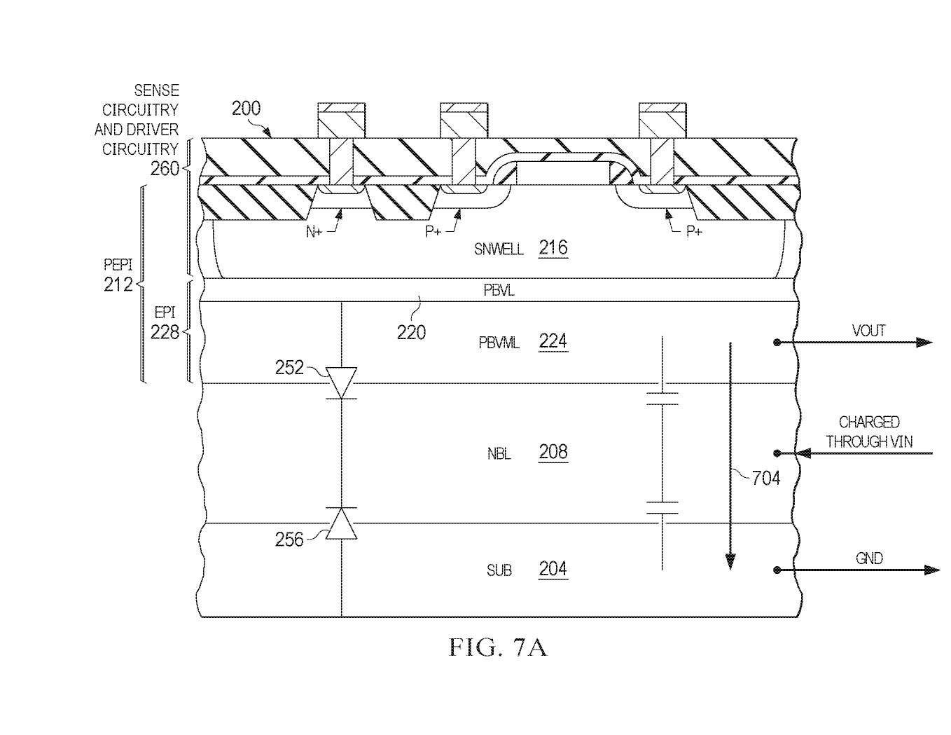

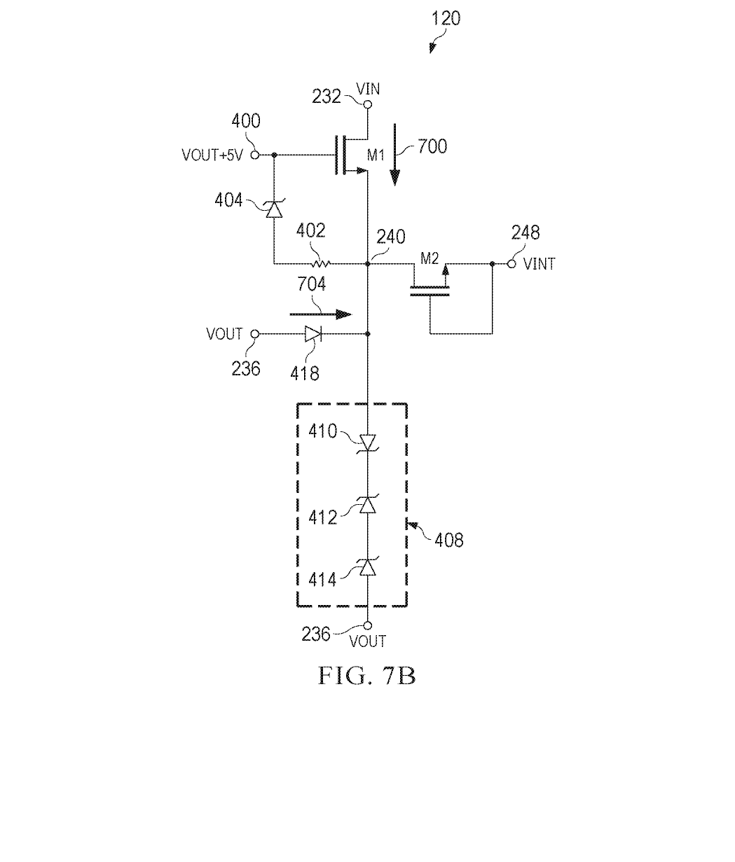

FIGS. 7A and 7B illustrate operations of the bias circuitry 120 during rising voltage conditions at the second terminal 236 (VOUT), demonstrating the charge mode functionality that maintains proper biasing of isolation tank structures during positive voltage transients, according to various examples. FIG. 7A shows the states of semiconductor device structure 200 caused by the bias circuitry 120 during VOUT rising conditions, and FIG. 7B shows the corresponding circuit operations of the bias circuitry 120 in such conditions. The VOUT rising condition represents the scenario where the output voltage at the second terminal 236 experiences positive voltage transitions that need charging of the NBL 208 capacitance to maintain proper voltage relationships between semiconductor layers.

During the VOUT rising conditions shown in FIG. 7A, the bias circuitry 120 operates in charge mode where the NBL 208 capacitance is charged through the first terminal 232 (VIN) to maintain proper voltage tracking with the second terminal 236 (VOUT). The current flow 700 in 7B indicates the charging current path from VIN through the first transistor M1 to the NBL 208, providing sufficient drive strength to charge the NBL-to-substrate capacitance of the isolation tank structure. Current flow 704 in FIGS. 7A and 7B indicates the voltage tracking relationship from VOUT at the second terminal 236 to the NBL at the third terminal 240, illustrating how the NBL voltage follows VOUT through the offset voltage generator 400, which provides VOUT+5V to control the gate of the first transistor M1. The sense circuitry and driver circuitry 260 implemented within the PEPI layer 212 benefit from this adaptive biasing strategy as the NBL 208 voltage tracks the VOUT voltage with appropriate headroom while the charging current is sourced from the stable VIN supply rather than from weaker derived supplies. Stated differently, the NBL 208 voltage follows changes in VOUT at the second terminal 236, and maintains sufficient voltage difference to keep semiconductor junctions properly biased. Moreover, the voltage at the first terminal 232 (VIN) provides robust current sourcing capability during high slew rate transients, while weaker derived supplies may collapse under the high current demands needed to charge the isolation tank capacitances rapidly. This current sourcing from VIN through the first terminal 232 rather than derived supplies prevents supply rail collapse that could occur if charging current demands exceed the current capability of weaker internal voltage sources. Accordingly, the adaptive biasing strategy adjusts the NBL 208 bias voltage based on changing conditions at the VOUT terminal to maintain proper operation.

The semiconductor device structure 200 during VOUT rising conditions demonstrates how the bias circuitry 120 maintains proper voltage relationships between the PEPI layer 212 and NBL 208 to prevent violation of semiconductor junction voltage ratings. The PEPI layer 212 is coupled to the second terminal 236 (VOUT) through device construction, ensuring that circuits requiring VOUT-referenced operation maintain proper biasing. The NBL 208 is charged to a voltage level determined by the operating region of the first transistor M1, with the voltage level being either VOUT+5V minus a gate to source voltage (VGS) of the first transistor M1 when the first transistor M1 operates in saturation or approaching VIN when the first transistor M1 operates in the linear region.

FIG. 7B shows the circuit operations during VOUT rising conditions, illustrating how the first transistor M1 operates as a source follower to provide the charging functionality. The first transistor M1 receives the gate bias voltage VOUT+5V from the offset voltage generator 400, turning on the first transistor M1 to allow the current flow 700, thereby enabling proper operation across varying voltage conditions at the second terminal 236. The source terminal of the first transistor M1 is coupled to the third terminal 240 (NBL), providing the charging current path from the first terminal 232 (VIN) to charge the NBL capacitance during rising voltage conditions at the second terminal 236.

While VOUT rises, the discharge circuit components including the Zener diode stack 408 and the second transistor M2 remain inactive, allowing the charging operation to proceed without interference. The Zener diode stack 408 does not conduct during normal rising voltage conditions as the voltage difference between the third terminal 240 and the second terminal 236 remains within normal operating limits. The second transistor M2 and its body diode remain non-conducting during positive voltage conditions at the second terminal 236, as the rectifying functionality is not required during VOUT rising scenarios.

The charge mode operation shown in FIGS. 7A and 7B enables the bias circuitry 120 to maintain fast charging rates while drawing current from the stable VIN supply, preventing supply rail collapse that could occur if charging current were drawn from weaker derived supplies. The adaptive biasing strategy ensures that the NBL 208 voltage follows the VOUT voltage with sufficient headroom to maintain reverse-bias across the second inherent diode 256 between the NBL 208 and the substrate layer 204, preventing charge injection to the substrate and maintaining electrical isolation during rising voltage transients.

The charging current capability provided by the first transistor M1 source follower configuration enables the bias circuitry 120 to handle high slew rate transients of up to about 1 GV/s, and maintains proper semiconductor junction voltage ratings and curtails latch-up conditions during positive voltage excursions at the second terminal 236. Stated differently, the charging current capability of the first transistor M1 in the source follower configuration can avoid a destructive parasitic effect where unintended transistor structures within the semiconductor device may be triggered into conduction, creating uncontrolled current paths that bypass the intended circuit operations and may cause permanent device damage or malfunction. Positive voltage excursions at the second terminal 236 describe scenarios where the VOUT voltage experiences rapid upward transitions that could potentially cause voltage differences between semiconductor layers to exceed safe limits without the adaptive charging provided by the first transistor M1. The source follower configuration of the first transistor M1 ensures that adequate current is available from the stable VIN supply to charge the NBL capacitance rapidly enough to track these voltage excursions and prevent the voltage buildup that could trigger parasitic devices or exceed junction breakdown voltages.

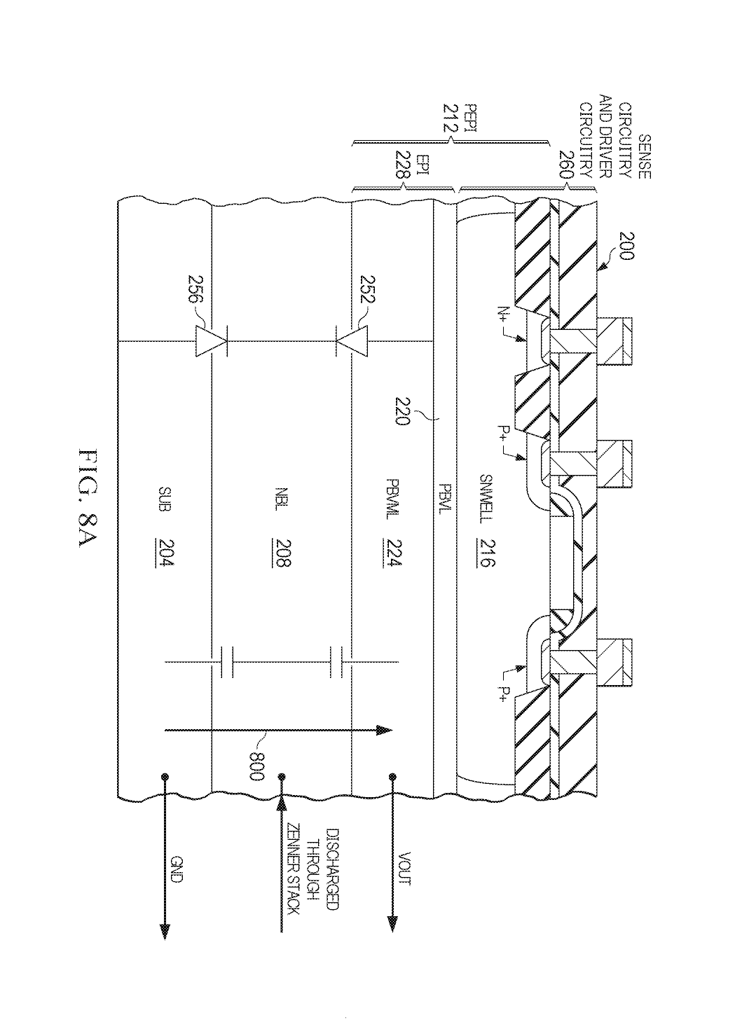

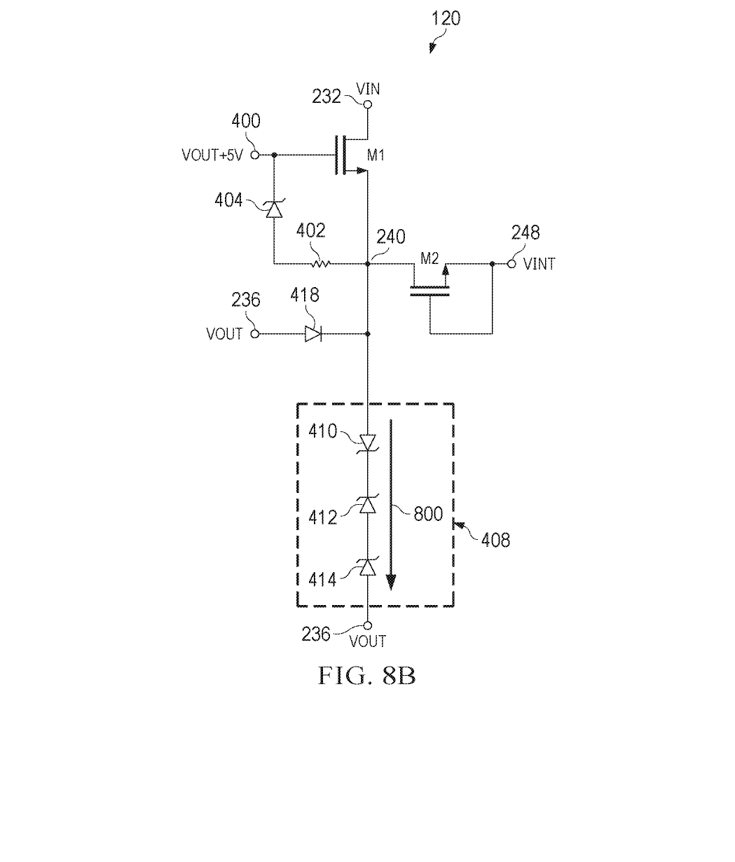

FIGS. 8A and 8B illustrate the operation of the bias circuitry 120 during falling voltage conditions at the second terminal 236 (VOUT), demonstrating the discharge mode functionality that maintains proper biasing of isolation tank structures during negative voltage transients, according to various examples. FIG. 8A shows the states of semiconductor device structure 200 caused by the bias circuitry 120 during VOUT falling conditions, and FIG. 8B shows the corresponding circuit operations during such conditions. The VOUT falling condition represents a scenario where the output voltage at the second terminal 236 experiences negative voltage transitions that need a rapid discharge of the NBL 208 capacitance to maintain proper voltage relationships between semiconductor layers and prevent violation of semiconductor junction voltage ratings.

During VOUT falling conditions shown in FIG. 8A, the bias circuitry 120 operates in discharge mode where the NBL 208 capacitance is discharged through the discharge circuit 304 to prevent excessive voltage buildup between the NBL 208 and PEPI layer 212. The current flow 800 in FIGS. 8A and 8B indicates the discharge current path from the NBL 208 through the Zener diode stack 408 to the second terminal 236 (VOUT), providing rapid discharge capability to prevent violation of semiconductor junction voltage ratings during high slew rate falling transients. The sense circuitry and driver circuitry 260 implemented within the PEPI layer 212 benefit from this adaptive biasing strategy as the voltage difference between the NBL 208 and PEPI layer 212 is maintained within semiconductor process limits even during transient conditions.

The semiconductor device structure 200 during VOUT falling conditions demonstrates how the bias circuitry 120 prevents violation of well voltage ratings by providing a controlled discharge path through the Zener diode stack 408. The PEPI layer 212 remains connected to the second terminal 236 (VOUT) through device construction, ensuring that circuits needing VOUT-referenced operation maintain proper connections during falling transient events. The NBL at the third terminal 240 discharges through the Zener diode stack 408 when the voltage difference between the third terminal 240 (NBL) and the second terminal 236 (VOUT) exceeds the predetermined breakdown voltage of approximately 12.7 V, preventing the voltage buildup from exceeding semiconductor junction breakdown limits.

FIG. 8B shows the circuit operations during VOUT falling conditions, illustrating how the Zener diode stack 408 provides the discharge functionality while other circuit components remain inactive during this operational mode. The first transistor M1 and the offset voltage generator 400 do not actively contribute to the discharge operation, allowing the Zener diode stack 408 to provide the primary discharge path without interference from the charging circuitry. The second transistor M2 and its body diode remain non-conducting during VOUT falling scenarios that maintain positive voltage levels, as the rectifying functionality is primarily activated during negative voltage conditions at the second terminal 236 (VOUT).

During VOUT falling operation, the Zener diode stack 408 conducts a current to enable the current flow 800 from the third terminal 240 (NBL) to the second terminal 236 (VOUT) during intervals of time the voltage difference exceeds the stack breakdown voltage, enabling rapid discharge of stored charge in the NBL-to-substrate capacitance. The discharge current path allows the voltage buildup between the NBL 208 and PEPI layer 212 to be contained to about 12 V during falling transients with slew rates up to about 1 GV/s. The controlled discharge indicated by the current flow 800 prevents violation of semiconductor junction voltage ratings, and maintains electrical isolation between the NBL 208 and the substrate layer 204.

The discharge mode operation shown in FIGS. 8A and 8B enables the bias circuitry 120 to handle high slew rate falling transients by providing a fast discharge path that limits voltage buildup between semiconductor tank layers within well voltage ratings. The adaptive biasing strategy ensures that the NBL 208 voltage tracks the falling VOUT voltage with controlled discharge timing to prevent excessive voltage differences that could cause device malfunction or failure. The discharge current capability provided by the Zener diode stack 408 enables the bias circuitry 120 to handle transient slew rates of up to about 1 GV/s and maintains proper semiconductor junction voltage ratings, thereby preventing charge injection to substrate regions during falling voltage transients at the second terminal 236.

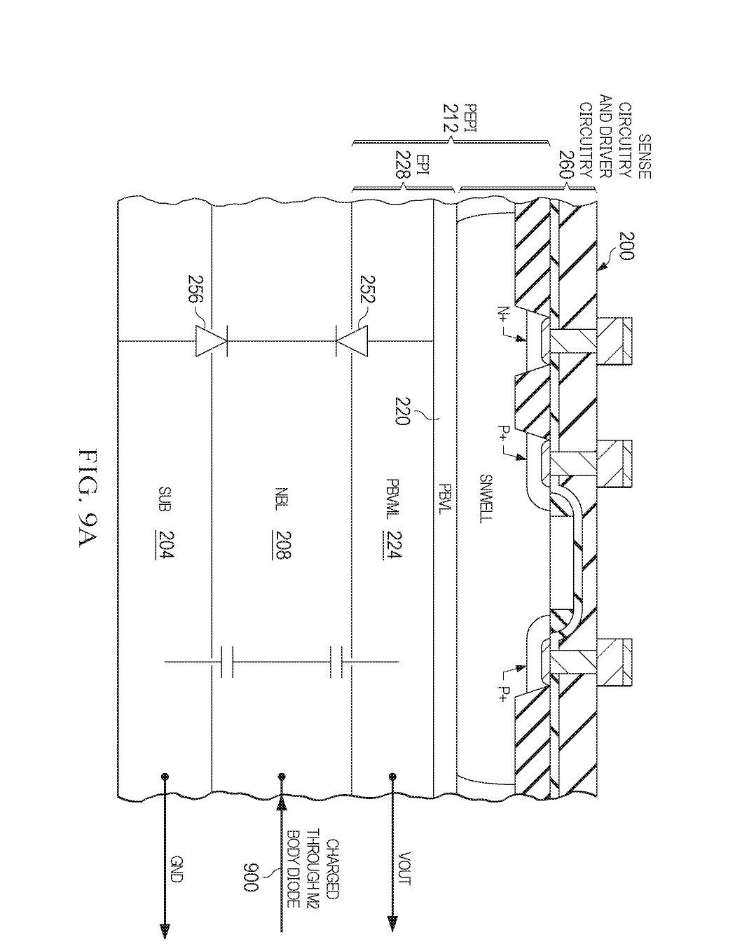

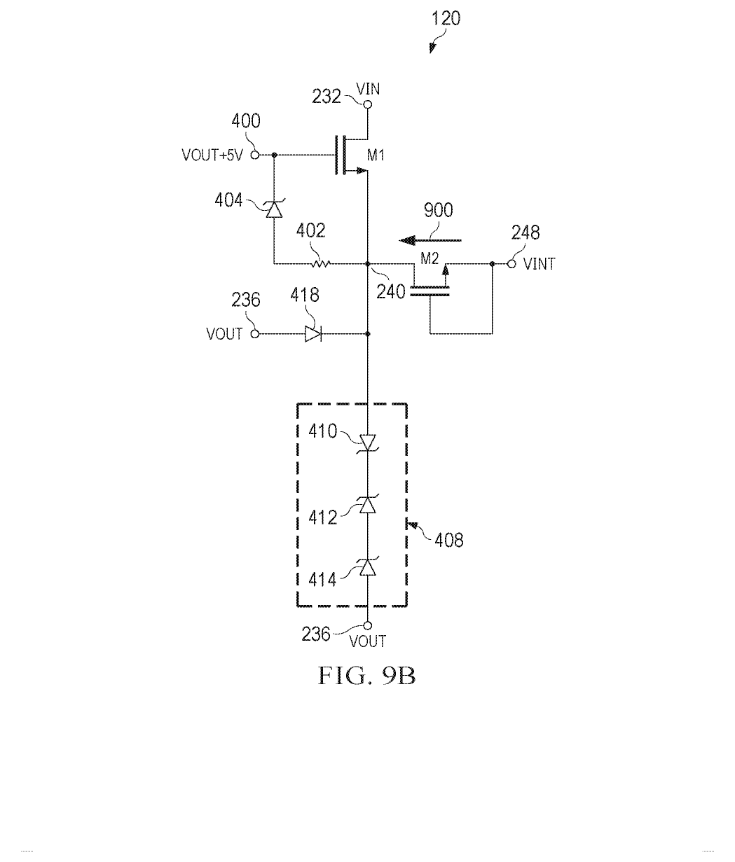

FIGS. 9A and 9B illustrate the operation of the bias circuitry 120 during negative voltage conditions at the second terminal 236 (VOUT), demonstrating the negative protection mode functionality that maintains proper biasing of isolation tank structures during negative voltage excursions, according to various examples. FIG. 9A shows the state of semiconductor device structure 200 caused by the bias circuitry 120 during VOUT DC negative conditions (e.g., VOUT has a negative DC level), and FIG. 9B shows the corresponding circuit operations during the same operational mode. The VOUT DC negative condition represents the scenario where the output voltage at the second terminal 236 experiences negative voltage excursions of up to about -5 V and the NBL 208 needs to be maintained at a positive voltage level to curtail forward biasing of substrate junctions and associated latch-up conditions.

As shown in FIG. 9A, when VOUT is a negative voltage (e.g., a negative DC voltage), the bias circuitry 120 operates in negative protection mode, where the NBL 208 at the third terminal 240 is maintained at a positive voltage level through conduction from the voltage source 248 via the body diode of the second transistor M2. The current flow 900 indicates the current path from VINT through the body diode of the second transistor M2 to the third terminal 240 (NBL 208) provides sufficient current to maintain the NBL 208 at approximately VINT minus the forward voltage drop of the body diode. The sense circuitry and driver circuitry 260 implemented within the PEPI layer 212 benefit from this adaptive biasing strategy as the NBL 208 voltage is prevented from following the negative excursions of the second terminal 236, maintaining proper isolation and preventing charge injection to the substrate layer 204.

The semiconductor device structure 200 during VOUT DC negative conditions demonstrates how the bias circuitry 120 prevents latch-up conditions by maintaining the NBL 208 at a positive voltage level while the PEPI layer 212 follows the negative voltage at the second terminal 236. Accordingly, the PEPI layer 212 remains connected to the second terminal 236 (VOUT) through device construction, allowing circuits needing VOUT-referenced operations to follow the negative excursions while maintaining electrical isolation. The NBL 208 is maintained at approximately 4.3 V (VINT minus the forward voltage drop of about 0.7 V) through conduction of the body diode of the second transistor M2, ensuring that the second inherent diode 256 between the NBL 208 and substrate layer 204 (represented as diode 418 in FIG. 9B) remains reverse-biased and prevents charge injection to the substrate.

FIG. 9B shows the circuit operations during VOUT DC negative conditions, illustrating how the second transistor M2 provides the negative protection functionality while other circuit components remain inactive during this operational mode. The first transistor M1 and the offset voltage generator 400 do not actively contribute to the negative protection operation, as the source follower configuration is designed for charging operations during positive voltage conditions. The Zener diode stack 408 does not conduct during VOUT DC negative scenarios, as the voltage difference between the third terminal 240 and the negative voltage at the second terminal 236 exceeds the breakdown voltage but in the reverse direction, allowing the rectifying functionality to take precedence.

When VOUT is negative, the voltage at the second terminal 236 (NBL), which tracks VOUT, may also be sufficiently negative to forward bias the body diode of the second transistor M2. Accordingly, the body diode of the second transistor M2 conducts current to enable the current flow 900 from the voltage source 248 (VINT at approximately 5 V) to the third terminal 240 (NBL 208) responsive to the voltage at the second terminal 236 becoming sufficiently negative to forward bias the body diode. The body diode maintains the third terminal 240 (NBL 208) at a voltage level of approximately VINT minus the forward voltage drop, preventing the NBL 208 from following the negative voltage excursions and ensuring that the second inherent diode 256 remains reverse-biased. The negative protection functionality enables the bias circuitry 120 to handle negative voltage excursions of up to about -5 V at the second terminal 236 while maintaining electrical isolation and preventing device malfunction.

The negative protection mode operation shown in FIGS. 9A and 9B enables the bias circuitry 120 to prevent latch-up conditions by maintaining the NBL 208 at a stable positive voltage level independent of negative voltage conditions at the second terminal 236. In this manner the protective biasing function operates independently of how far the VOUT voltage swings below ground potential, whether due to inductive kickback during switching events, external circuit transients, or other phenomena that drive the output terminal negative. Thus, the adaptive biasing strategy ensures that substrate junctions remain properly biased to prevent charge injection to the substrate layer 204, maintaining electrical isolation during electrical stress conditions. The current capability provided by the voltage source 248 through the body diode of the second transistor M2 enables the bias circuitry 120 to handle negative voltage excursions and maintains proper semiconductor junction voltage ratings and to curtail forward biasing of critical junctions that could lead to latch-up conditions and device failure during negative voltage events at the second terminal 236.

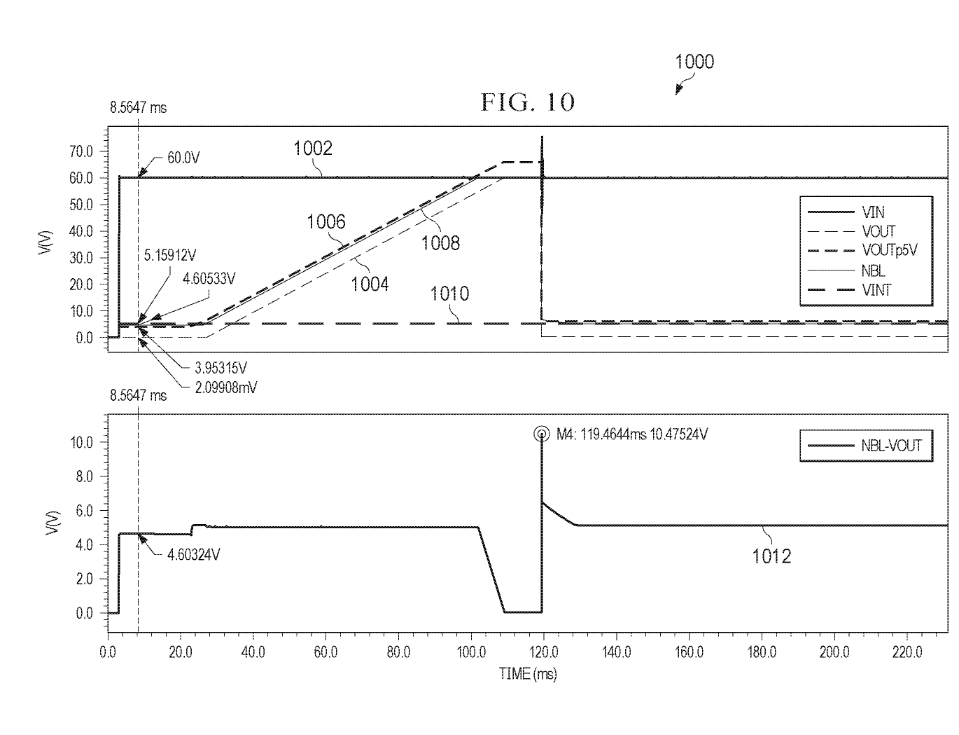

FIG. 10 illustrates a graph 1000 with results that demonstrate an example of the operational performance of the bias circuitry 120 across varying voltage conditions at the second terminal 236. The graph 1000 shows the effectiveness of the adaptive biasing strategy during different operational modes, according to various examples. The graph 1000 illustrates operations described in FIGS. 7A-9B, including charge mode during rising voltage conditions, discharge mode during falling transients, and negative protection mode during negative voltage excursions. The graph 1000 plots voltages as a function of time over a time period of approximately 220 milliseconds and demonstrates voltage ranges from approximately 0 V to +70 V at the second terminal 236, validating the specified operating range of the bias circuitry 120.

The graph 1000 includes multiple voltage plots that illustrate the coordinated operation of the bias circuitry 120 components during transient events. The plot 1002 illustrates the input voltage VIN maintaining a stable level of approximately 60 V, providing the stable supply source for charging operations through the first terminal 232. The plot 1004 illustrates the output voltage VOUT at the second terminal 236 undergoing various transient conditions including rising voltage transitions, falling voltage transients, and negative voltage excursions that exercise the three operational modes of the bias circuitry 120. The plot 1006 illustrates offset voltage VOUT+5V (labelled VOUTp5V) from the offset voltage generator 400 tracking the second terminal 236 voltage and maintaining the predetermined 5 V offset needed for proper operation of the first transistor M1.

The plot 1008 demonstrates the NBL voltage at the third terminal 240 responding appropriately to the different operational conditions at the second terminal 236. During steady-state operation (e.g., after about 125 milliseconds), the graph 1000 shows the NBL voltage reaching approximately the VIN level, indicating that the first transistor M1 operates in the linear region and provides a low-resistance path from the first terminal 232 to the third terminal 240. During power-up sequences, from 0 ms to about 100 ms, the graph 1000 shows the NBL voltage charging to approximately VOUT+5V minus the gate-to-source voltage of the first transistor M1, demonstrating the source follower operation during intervals of time the first transistor M1 operates in the saturation region. The plot 1010 illustrates the internal voltage VINT maintaining a stable level of approximately 5 V, providing the positive reference voltage for negative protection mode operation.

The plot 1012 illustrates a voltage difference NBL-VOUT, which represents the voltage difference between the third terminal 240 and the second terminal 236. This differential voltage trace demonstrates the effectiveness of the discharge circuit 304 in limiting voltage buildup between semiconductor tank layers during falling voltage transients. The plot 1012 shows that during voltage transients (e.g., between about 100 and about 130 ms) including an interval where the slew rates are approximately 500 V per microsecond (V/µs) (e.g. between about 100 ms and about 110 ms), the voltage difference between the NBL and VOUT is contained to approximately 12 V, within semiconductor process limits and preventing violation of well voltage ratings. The controlled voltage difference prevents device malfunction and maintains electrical isolation during transient conditions.

Various plots of the graph 1000 demonstrates the performance specifications of the bias circuitry 120 across the three operational modes described in FIGS. 7A-9B. During charge mode operation occurring from approximately 0 to 20 ms and again from approximately 140 ms onward, the graph 1000 illustrates that the first transistor M1 successfully charges the third terminal 240 from the stable VIN supply and maintains proper voltage tracking with the second terminal 236. During discharge mode operation occurring from approximately 100 to 120 milliseconds, the graph 1000 illustrates that the Zener diode stack 408 provides rapid discharge capability that limits voltage buildup to acceptable levels during high slew rate falling transients, with the NBL-VOUT differential voltage trace showing controlled voltage differences during these intervals. Additionally, during negative protection mode operation, which would occur during any intervals when VOUT experiences negative excursions below ground potential, the rectifying device 312 (implemented with the second transistor M2) maintains the third terminal 240 (NBL) at positive voltage levels if the second terminal 236 experiences negative excursions, curtailing charge injection to substrate regions and associated latch-up conditions.

The graph 1000 demonstrates the ability of the bias circuitry 120 to handle transient slew rates of up to approximately 1 GV/s and maintain proper semiconductor junction voltage ratings and preventing device malfunction. The coordinated operation of the charge circuit 300, the discharge circuit 304, and the rectifying device 312 enables reliable operation across voltage ranges from approximately -5 V to +80 V at the second terminal 236. The graph 1000 provides quantitative evidence that the adaptive biasing strategy maintains electrical isolation within semiconductor structures while preventing charge injection to substrate regions during electrical stress conditions.

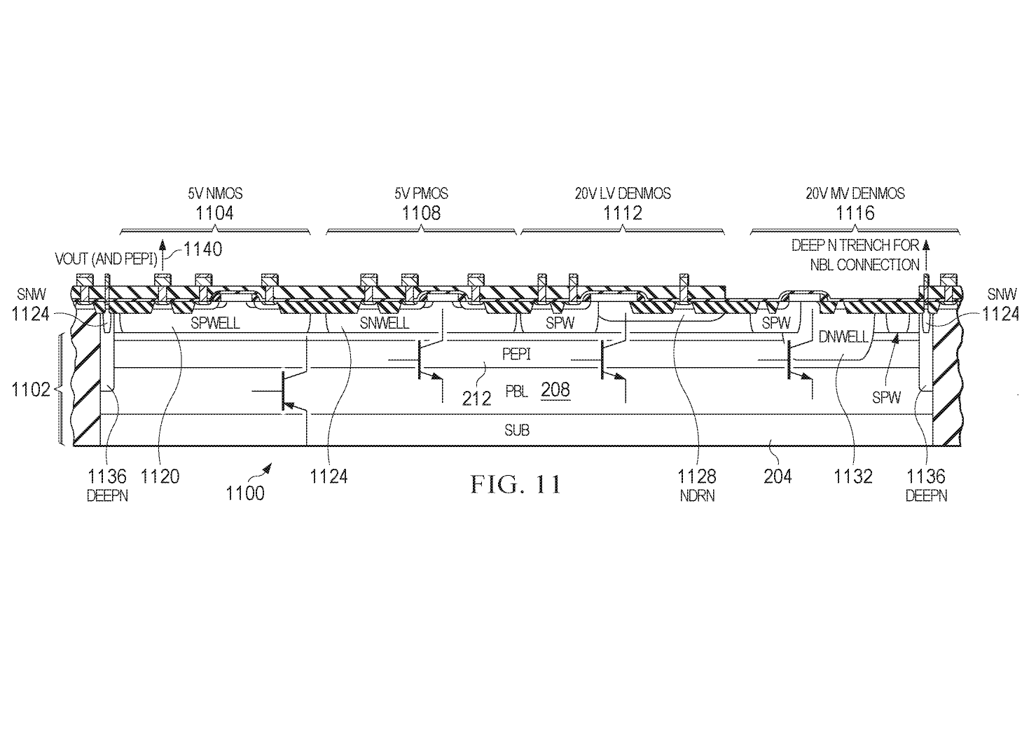

FIG. 11 illustrates a semiconductor device structure 1100 including multiple voltage rating devices within a single semiconductor substrate, according to various examples. The semiconductor device structure 1100 can include the semiconductor device structure 200 of FIG. 2 and can be connected to the bias circuitry 120 to maintaining proper isolation and biasing. The semiconductor device structure 1100 shows how different voltage ratings may be accommodated within the same semiconductor technology while providing the needed connections for the adaptive biasing strategy described in FIGS. 1-10. The semiconductor device structure 1100 represents an expanded view of the semiconductor implementation that supports various circuit elements including 5V devices, 20V devices, and the biasing infrastructure necessary for proper tank node control.

The semiconductor device structure 1100 includes a substrate foundation 1102 that supports multiple semiconductor regions designed for different voltage rating requirements. The substrate foundation 1102 includes the substrate layer 204 (SUB), the NBL 208 and the PEPI layer 212 of FIG. 2. The semiconductor device structure 1100 include a 5V NFET region 1104 configured to support low-voltage N-channel metal-oxide-semiconductor devices with voltage ratings appropriate for 5 V operation. The semiconductor device structure 1100 includes 5V PMOS region 1108 configured to support low-voltage P-channel metal-oxide-semiconductor devices with corresponding 5 V voltage ratings. The semiconductor device structure 1100 includes a 20V LV DENMOS (Low Voltage Drain-Extended n-channel metal-oxide semiconductor (NMOS)) region 1112 configured to support medium-voltage applications with 20 V rating capabilities. The semiconductor device structure 1100 includes a 20V MV DENMOS (Medium Voltage Drain-Extended NMOS) region 1116 configured to support higher voltage applications within the 20 V range while providing enhanced voltage handling capabilities.

The semiconductor device structure 1100 includes various well structures that provide isolation and proper biasing for the different voltage rating regions. The semiconductor device structure 1100 includes a shallow P-well (spwell) 1120 formed within the substrate to provide body connections and isolation for N-channel devices. The semiconductor device structure 1100 includes a shallow N-well (snwell) 1124 formed within the substrate to provide body connections and isolation for P-channel devices. The semiconductor device structure 1100 includes an N-type drain region (ndrn) 1128 that provide drain connections for various device types within the semiconductor structure. The semiconductor device structure 1100 includes deep N-wells (dnwell) 1132 that provide enhanced isolation and voltage handling capability for higher voltage applications.

The semiconductor device structure 1100 demonstrates the implementation of a deep N trench 1136 that provide the physical connection path between the NBL and external terminals for biasing control. The deep N trench 1136 extends from the surface of the semiconductor device structure 1100 down to the NBL 208, providing the electrical pathway that enables the third terminal 240 connection described in previous figures. The deep N trench 1136 represents the physical implementation of the NBL connection that allows the bias circuitry 120 to control the voltage level of the NBL across the various device types and voltage ratings within the semiconductor device structure 1100. The deep N trench 1136 enables application of the adaptive biasing strategy across the semiconductor device structure 1100, independent of the voltage rating of individual circuit regions.

The semiconductor device structure 1100 includes VOUT connections 1140 that demonstrate how the connections of PEPI layer 212 are distributed across the various voltage rating regions. The VOUT connections 1140 provide the physical interface that connects the PEPI layer 212 to the second terminal 236 described in previous figures, enabling VOUT-referenced operation across device types within the semiconductor device structure 1100. The semiconductor device structure 1100 shows how the PEPI layer 212 serves as the common foundation that supports different device types and maintaining the connection to VOUT through device construction.

The semiconductor device structure 1100 illustrates the deep trench isolation that enables multiple device types with different voltage ratings to coexist within the same semiconductor substrate while maintaining electrical isolation between regions. The deep trenches filled with insulating material provide isolation barriers that prevent unwanted electrical interaction between adjacent circuit regions while allowing the NBL and PEPI biasing strategy to be applied across the structure with varied voltage levels. The semiconductor device structure 1100 demonstrates that the adaptive biasing strategy described in FIGS. 1-9B may be implemented across a wide range of device types and voltage ratings within a single integrated circuit implementation.

In some examples, the bias circuitry 120 can be implemented in the PEPI layer 212. The bias circuitry 120 can be connected to the NBL 208 via deep N trench connections and metal interconnects above (not shown), and connected to the VOUT connections 1140 and metal interconnects above (not shown).

The implementation shown in FIG. 11 enables the bias circuitry 120 to provide comprehensive protection for isolation tank structures across multiple voltage domains, maintaining the three-mode operation capability described in previous figures. The deep N trench 1136 enables connections ensuring that the charge mode, the discharge mode, and the negative protection mode functionality may be applied uniformly (or nearly so) to device regions independent of the specific voltage ratings. The semiconductor device structure 1100 supports voltage ranges from 5 V to 20 V for local device operation while maintaining the overall system capability to handle voltage ranges from approximately -5 V to +80 V at the second terminal 236 through the coordinated operation of the bias circuitry 120. The semiconductor device structure 1100 implementation provides the foundation for E-fuse protection systems that may handle electrical stress conditions and maintain proper device isolation and curtail charge injection to substrate regions.

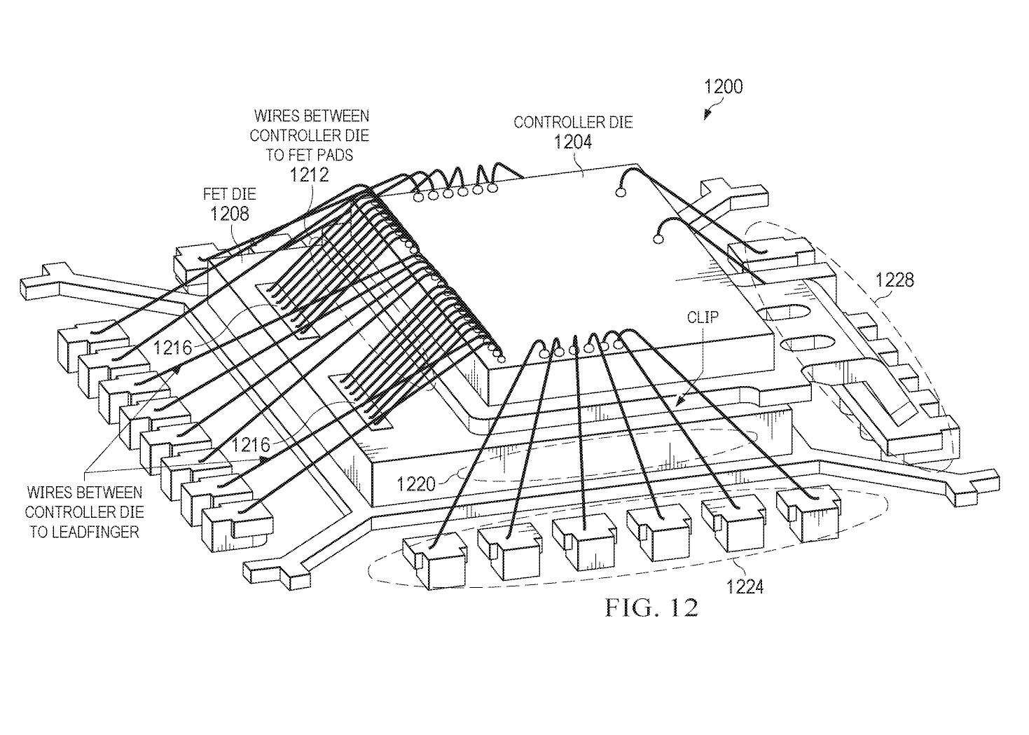

FIG. 12 illustrates a multi-die implementation of a semiconductor package 1200 of the E-fuse protection system 100 from FIG. 1, showing the physical packaging architecture that enables the FET and controller to be implemented on separate semiconductor dies and maintaining the functionality of the bias circuitry 120, according to various examples. FIG. 12 demonstrates how the adaptive biasing strategy described in FIGS. 1-11 may be implemented in a practical multi-chip module configuration tuned to enable both the power handling capabilities and the control circuit performance.

The semiconductor package 1200 includes a controller die 1204 positioned above a FET die 1208 in a stacked configuration within a semiconductor package. The controller die 1204 contains the controller 112 from FIG. 1, including the driver circuitry 114, the sense circuitry 116, and the bias circuitry 120 that provide the adaptive biasing functionality described in FIGS. 1-11, and may include the semiconductor device structures 200 and 1100. The controller die 1204 is implemented using a first semiconductor technology tuned for control circuit functionality, analog signal processing, and the complex biasing strategies required to handle the electrical stress conditions described in previous figures. The FET die 1208 contains the FET 110 from FIG. 1 and is implemented using a second semiconductor technology tuned for high-power switching applications, vertical FET structures, and low on-resistance characteristics in some examples.

The semiconductor package 1200 includes wire bond connections 1212 that provide electrical interconnection between the controller die 1204 and FET pads 1216 on the FET die 1208. The wire bond connections 1212 (only some of which are labeled) enable the driver circuitry 114 on the controller die 1204 to provide control signals to the gate terminal of the FET 110 on the FET die 1208, maintaining the control functionality described in FIG. 1. The semiconductor package 1200 includes additional wire bond connections 1220 (only some of which are labeled) between the controller die 1204 and lead connections 1224 (only some of which are labeled) that provide external terminal access to the semiconductor package. The wire bond connections 1220 enable the bias circuitry 120 to receive the input voltage VIN and monitor the output voltage VOUT as described in the terminal connections of FIGS. 2-11.

The semiconductor package 1200 includes CLIP connections 1228 that provide low-inductance, high-current connections between the FET die 1208 and external terminals. The CLIP connections 1228 enable the high-current power delivery for the FET 110, enabling the E-fuse protection system 100 to handle the current and voltage stress conditions described in the technical environment. The CLIP connections 1228 provide improved electrical and thermal performance for the high-power switching applications, reducing parasitic inductance and resistance that could otherwise impact the transient response during the high slew rate events that the bias circuitry 120 is designed to handle.

The multi-die architecture shown in FIG. 12 enables process selection where the controller die 1204 can be manufactured using a semiconductor process tuned for analog and digital control circuits, while the FET die 1208 may be manufactured using a vertical FET process tuned for high-voltage, high-current switching applications. This process separation enables the bias circuitry 120 implemented on the controller die 1204 to utilize the precise analog circuit elements described in FIGS. 4-6, including the offset voltage generator 400, the voltage source 248, and the Zener diode stack 408, without the process compromises needed in a single-die implementation, attempting to balance both power and control functions.

The semiconductor package 1200 maintains the full functionality of the adaptive biasing strategy described in FIGS. 7A-9B, with the controller die 1204 providing the three-mode operation (charge mode, discharge mode, and negative protection mode) for the isolation tank structures within the sense circuitry 116. The wire bond connections 1212 and 1220 provide the electrical paths for the bias circuitry 120 to monitor the second terminal 236 (VOUT) and control the third terminal 240 (NBL) connections described in previous figures, and the CLIP connections 1228 handle the high-current power delivery paths. The multi-die approach enables the bias circuitry 120 to maintain the voltage range from approximately -5 V to +80 V at VOUT and handle transient slew rates of up to about 1 GV/s while providing the thermal and electrical isolation needed for reliable operation in demanding applications. Additionally, the multi-die implementation of the semiconductor package 1200 enables the comprehensive semiconductor tank node protection described in FIG. 11 to be implemented across multiple voltage domains and device types while maintaining the manufacturing efficiency and reliability needed for high-volume production of E-fuse protection devices for server, automotive, and industrial applications.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” or “configurable to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor components.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT – e.g., NPN transistor or PNP transistor), an insulated gate bipolar transistor (IGBT), and/or a junction field effect transistor (JFET) may be used in place of or in conjunction with the devices described herein. The transistors may be in depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/- 10 percent of that parameter or, if the parameter is zero, a reasonable range of values around zero.

What is claimed is:

1. An apparatus comprising:
a semiconductor device including a first semiconductor layer (PEPI) and a second semiconductor layer (NBL), the first semiconductor layer having dopants of opposite polarities, the semiconductor device includes a bias circuit implemented in the first semiconductor layer, in which:
the bias circuit has a first terminal (VIN), a second terminal (VOUT), a third terminal (NBL) and a fourth terminal (VINT), the second terminal is coupled to the first semiconductor layer, and the third terminal is coupled to the second semiconductor layer; and
the bias circuit includes:
a charge circuit coupled between the first terminal and the third terminal,
a discharge circuit coupled between the third terminal and the second terminal, and
a rectifying device coupled between the third terminal and the fourth terminal.

2. The apparatus of claim 1, wherein the first semiconductor layer is a P-type epi layer and the second semiconductor layer is an N-type buried layer.

3. The apparatus of claim 1, wherein the second semiconductor layer is configurable as an isolation tank.

4. The apparatus of claim 1, wherein the charge circuit includes a source follower circuit having a control terminal coupled to the second terminal and an output coupled to the third terminal.

5. The apparatus of claim 4, wherein the charge circuit further comprises a diode and a resistor coupled between the control terminal and the third terminal.

6. The apparatus of claim 1, wherein the charge circuit includes a first voltage generator configurable to provide a first voltage by adding a voltage offset to a second voltage at the second terminal.

7. The apparatus of claim 1, wherein the discharge circuit includes:
a first diode having an anode coupled to the third terminal,
a second diode having a cathode coupled to a cathode of the first diode, and
a third diode having a cathode coupled to an anode of the second diode and anode coupled to the second terminal.

8. The apparatus of claim 1, wherein the bias circuit is configurable to charge the third terminal during rising voltage conditions at the second terminal by sourcing current from the first terminal through the charge circuit.

9. The apparatus of claim 1, wherein the bias circuit is configurable to discharge the third terminal during falling voltage transients at the second terminal through the discharge circuit to limit voltage buildup between the third terminal and the second terminal.

10. The apparatus of claim 1, wherein during negative voltage conditions at the second terminal, the rectifying device conducts current from the fourth terminal to maintain the third terminal at a positive voltage level.

11. The apparatus of claim 1, wherein the semiconductor device further comprises a drive circuit having an input coupled to a sense circuit and having a drive output.

12. The apparatus of claim 11, further comprising a FET (field-effect transistor) external to the semiconductor device, the FET coupled between the first terminal and the second terminal, wherein the FET includes a control terminal coupled to the drive output.

13. An apparatus comprising:
a switch coupled between a power input and a power output, the switch having a switch control terminal;
a semiconductor device including a first semiconductor layer, a second semiconductor layer, and a substrate, the first and second semiconductor layers having dopants of opposite polarities, and the second semiconductor layer and the substrate having dopants of opposite polarities, in which:
the first semiconductor layer includes a drive circuit, a sense circuit, and a bias circuit;
the drive circuit has an input and an output, the output of the drive circuit coupled to the switch control terminal;
the sense circuit has an input and an output, the input of the sense circuit is coupled to the power output, and the output of the sense circuit is coupled to the drive circuit;
the bias circuit has a first terminal, a second terminal, a third terminal and a fourth terminal, the second terminal is coupled to the power output, and the third terminal is coupled to the second semiconductor layer; and
the bias circuit includes:
a charge circuit coupled between the first terminal and the third terminal,
a discharge circuit coupled between the third terminal and the second terminal, and
a rectifying device coupled between the third terminal and the fourth terminal.

14. The apparatus of claim 13, wherein the charge circuit includes a source follower circuit having a control terminal coupled to the second terminal and an output coupled to the third terminal.

15. The apparatus of claim 13, wherein the discharge circuit includes a diode stack coupled between the third terminal and the second terminal.

16. The apparatus of claim 13, wherein the rectifying device comprises a transistor having a body diode that conducts current from the fourth terminal to the third terminal when the second terminal becomes negative.

17. The apparatus of claim 13, wherein the apparatus is configurable to support a voltage at the power output within a range of about -5 volts to about +80 volts and transient slew rates of up to about 1 gigavolts per second.

18. A device comprising:
a transistor coupled between a power input and a power output, the transistor having a control terminal;
control and sensing circuitry coupled to the power input, power output, and the control terminal, the control and sensing circuitry being on an isolation tank and a semiconductor substrate; and
a biasing circuit coupled to the power input, the power output, and the isolation tank, the bias circuit configurable to charge the isolation tank responsive to a rising voltage at the power output, discharge the isolation tank responsive to a falling voltage at the power output, and maintain a non-zero voltage at the isolation tank responsive to a negative voltage at the power output.

19. The device of claim 18, wherein the isolation tank is an n-type layer and forms a p-n junction with a p-type layer coupled to the power output, and the biasing circuit is configurable to source a charging current from the power input responsive to the rising voltage at the power output to charge the isolation tank and to maintain the p-n junction in a reverse-bias state.

20. The device of claim 18, wherein the semiconductor substrate is p-type and forms a p-n junction with the isolation tank, and the biasing circuit is configurable to set discharge of the isolation tank responsive to the falling voltage at the power output and to maintain the p-n junction in a reverse-bias state.
